(19) United States
(12) Patent Application Publication
(10) Pub. No.: US 2002/0027461 A1
(43) Pub. Date: Mar. 7, 2002

(54) Semiconductor integrated circuit with suppressed clock skew

(76) Inventor: Mitsugu Kusunoki, Kunitachi (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/944,134

(22) Filed: Sep. 4, 2001

(30) Foreign Application Priority Data
Sep. 4, 2000 (JP) 2000-266971

(51) Int. Cl. H03K 5/01

(52) U.S. Cl. 327/165

(57) ABSTRACT

A semiconductor integrated circuit is disclosed, in which a plurality of circuit blocks each having a clock distribution line pattern, a first signal path for transmitting the data signal from a first circuit block to a second circuit block, a second signal path for transmitting a clock signal, at least a first buffer circuit connected to the first signal path to constitute the first signal path, and a second buffer circuit connected to the second signal path to configure the second signal path are formed on a single semiconductor chip. The first and second signal paths have the same length, and data and clock are transmitted in parallel to each other on the first and second signal paths, respectively. The second circuit block latches the received data by the clock transmitted in parallel.

### BACKGROUND OF THE INVENTION

The present invention relates to a semiconductor integrated circuit or a technique effectively applicable to a method of sync clock signal distribution on a semiconductor chip, or for example, a technique effectively applicable to a method of supplying a clock signal for data transmission between blocks of a system LSI.

In a logic LSI (large scale integrated circuit), a clock signal (hereinafter referred to simply as “the clock”) supplied from an external source is distributed over the whole LSI, so that data or signals are transmitted or transferred to flip-flops in synchronism with the clock. In distributing the external clock over the whole LSI, what is called a clock skew is caused in which the clock arrives at different timings due to the difference of the length of wiring conductors. In the presence of a clock skew, the flip-flop is liable to receiver or take an erroneous data or an undesirable spike is generated in the output signal of the logic gate which causes a malfunction of the circuit in the next stage. In the conventional methods employed to reduce the clock skew, the clock is supplied to each part of a chip by equal-length wiring conductors in a tree progressively branching from the chip center to the terminal circuits (JP-A-11-202971 laid-open Jul. 30, 1999, and JP-A-5-159080 laid-open Jun. 25, 1993).

With the recent progress of the semiconductor process, on the other hand, the clock frequency, i.e. the operating frequency of the chip has reached as high as more than 1 GHz. Also, an increased integration degree has come to provide a system LSI comprising a plurality of processors or having a large-scale cache memory which are built in a single chip instead of a plurality of chips conventionally used to provide a plurality of functions.

### SUMMARY OF THE INVENTION

It is common practice to employ a method using a clock distribution line pattern synchronized over the whole semiconductor chip from the viewpoint of logic design, diagnosis, etc. In this clock distribution line pattern, the clock skew is proportional to the area of the particular pattern. Therefore, the clock skew increases with the chip size, and even for chips of the same size, the clock skew increases with the clock frequency for a higher ratio of the clock skew to the clock period, thereby adversely affecting an attempt to increase the operating frequency of the LSI.

With the increase in the operating frequency, on the other hand, long-distance data transmission within a chip leads to a long signal delay time equivalent to several cycles. In view of this, the present inventor has studied a method using a plurality of flip-flops inserted on a signal transmission route, in which data are transmitted by being latched in each of the flip-flops for each cycle, thereby sequentially transmitting the data to subsequent stages. This method requires a design taking into account the clock skew (tck) and the flip-flop set-up time (tsu) and the delay margin (tpd). Specifically, in the case where N cycles are required for transmission, for example, the transmission time assumes a value equal to the sum of the real delay and N×(tck+tsu+tpd). The resulting necessity of determining the clock frequency taking this factor into account makes high-speed transmission difficult. U.S. Pat. No. 6,078,623 issued Jun. 20, 2000 (corresponding to WO 96/29655) is an example of the invention in which data and the clock are transmitted between LSIs on a board to control the clock skew.

An object of the present invention is to provide a clock distribution technique which can reduce the ratio of the clock skew to the transmission cycle, i.e. the clock period and thereby makes it possible to increase the operating frequency.

Another object of the invention is to provide a clock supply technique which can shorten the delay time in the long-distance data transmission within a chip and can transmit data accurately.

Still another object of the invention is to provide a clock supply technique which can suppress the total power consumption even with an increased operating frequency.

The above and other objects, features and advantages will be made apparent by the detailed description taken in conjunction with the accompanying drawings.

Representative aspects of the present invention disclosed herein will be briefly described below.

According to one aspect of the invention, there is provided a semiconductor integrated circuit such as a system LSI comprising a plurality of function blocks such as processors and memories in a single semiconductor chip, wherein a separate clock distribution line pattern is provided for each of the function blocks. The clock skew is roughly proportional to the length of the wiring conductors of the clock distribution line pattern. With the progress of the process, however, the chip area is not reduced nor the length of the wiring conductors of the clock distribution line pattern is shortened even though the operating frequency and the integration degree are increased. Thus, the clock skew occurs at a higher ratio. In the case where the clock distribution line pattern is provided for each function block as described, however, the area of each clock distribution line pattern is decreased and the clock wiring conductor length is reduced for a smaller clock skew, resulting in an increased operating frequency.

With a chip having a clock distribution line pattern for each function block as described above, however, an attempt to transmit data between blocks would increase the signal delay in the long-distance transmission on the one hand and increase the difference of the clock skew between blocks. An idea to make transmission possible any way under this condition is to reduce the clock frequency only for the long-distance transmission between blocks. In this method, however, a large volume of data cannot be transmitted at high speed. Another idea recently developed is to introduce into the chip the clock parallel transmission method for signal transmission between semiconductor chips on a large-sized board system.

The clock parallel transmission is a method in which the clock is transmitted in parallel to the data. As long as the data transmission and the clock transmission are designed to have the same length of wiring conductors, the clock skew relative to the transmission data is eliminated, and the data can be received successfully with the parallel clock at the receiving end. The use of this method eliminates the need of arranging flip-flops midway of the data transmission path, and therefore the delay time (tck+tsu+tpd) for each of N flip-flops arranged midway of the transmission path is not required to be taken into account.

A direct attempt to introduce into a chip the data transmission method using the parallel clock transmission which have thus far been employed between devices or chips on a system, however, poses the following problem. Specifically, in view of the fact that the resistance of internal wiring conductors of the chip is large as compared with the resistance of the coaxial cable used for signal transmission between devices or the resistance of the transmission lines of the board used for a system, the signal rise time tr and the signal fall time tf become so large that what is called the multi-cycle transmission is difficult in which the next data is transmitted to a given block before the preceding data arrives at the particular block. Increasing the width and thickness of the wiring conductors to reduce the wiring resistance in the chip to substantially the same value as in the transmission lines on the board may be a solution to this problem. An excessively large width of the wiring conductors, however, makes it necessary to reduce the number of wiring conductors considerably for data transmission due to the limited area. Also, an increased thickness of the wiring conductor layer impractically imposes an excessively large burden on the process.

In view of this, the clock is transmitted in parallel to the transmission data using an equal-length wiring conductor as a method of inter-block long-distance transmission, in which it is desirable, at the receiving end, to latch the received data with the clock transmitted in parallel. Further, the inter-block transmission wiring conductors may have a buffer arranged at each interval of a predetermined length.

### BRIEF DESCRIPTION OF THE DRAWINGS

FIG. 1 is a block diagram showing a block configuration of a semiconductor integrated circuit as a whole and the connections for transmitting/receiving signals between blocks according to a first embodiment of the invention.

FIG. 2 is a diagram showing a detailed circuit configuration for transmitting/receiving signals between a main circuit block CB0 and a given one of subsidiary circuit blocks CBi in FIG. 1.

FIG. 3 is a diagram showing a specific example of a configuration of a phase adjusting circuit in FIG. 2.

FIG. 4 is a diagram specifically showing a logic gate as a specific example of a delay stage circuit making up a variable delay circuit in FIG. 3.

FIG. 5 is a block diagram showing the configuration of a semiconductor integrated circuit as a whole and the connections for transmitting/receiving signals between blocks according to a second embodiment of the invention.

FIG. 6 is a diagram showing a detailed circuit configuration for transmitting/receiving signals between a main circuit block PB and a given one of subsidiary circuit blocks CB in FIG. 5.

FIG. 7 is a timing chart showing an example of timing of the clock and signals output from the main circuit block PB in FIG. 5.

FIG. 8 is a timing chart showing an example of timing of the signals in the clock receiving section and the circuit portion for generating a data latch timing of the subsidiary circuit block PB.

FIG. 9 is a timing chart showing an example of timing of the signals in the data receiving section of the main circuit block PB.

FIG. 10 is a diagram showing a configuration of a specific example of the phase adjusting circuit in FIG. 5.

FIG. 11 is a timing chart showing an example of timing of the signals in the phase adjusting circuit of FIG. 10.

FIGS. 12A to 12C show a circuit configuration and a layout of a specific example of a buffer circuit arranged on an inter-block signal transmission path of a semiconductor integrated circuit according to an embodiment of the present invention.

FIG. 13 is a sectional view for explaining a specific example of the wiring structure of a semiconductor integrated circuit according to an embodiment of the present invention.

### DESCRIPTION OF THE EMBODIMENTS

(First Embodiment)

An embodiment of the invention will be explained below with reference to the accompanying drawings.

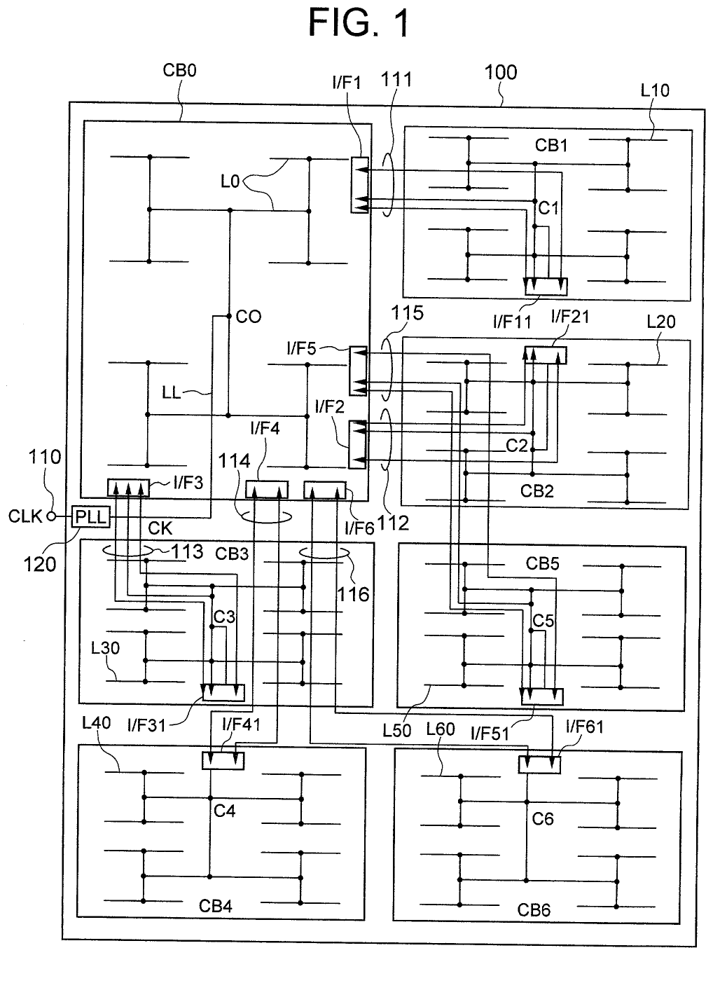

FIG. 1 shows a block configuration of a semiconductor integrated circuit as a whole and the connections for transmitting/receiving the signals between the blocks according to a first embodiment of the invention.

In FIG. 1, reference numeral 100 designates a semiconductor chip such as a single crystal silicon, numeral 110 a clock input terminal supplied with the clock signal from an external source, and CB0, CB1, CB2, CB3, CB4, CB5, CB6 macro circuit blocks having substantially independent functions formed on the chip 100. Each circuit block is configured of a CMOS circuit, for example.

According to this embodiment, the block CB0 is a main circuit block such as a processor having the function as a center of a plurality of blocks on the chip, and the blocks CB1 to CB6 are subsidiary circuit blocks such as a ROM, a RAM or a cache memory. Other examples of the subsidiary circuit blocks than the memories may include a peripheral circuit module such as an interrupt control circuit, a timer circuit, an A/D or D/A conversion circuit for a single-chip microcomputer, or a user logic circuit having a logic function desired by the user for a custom LSI.

In this embodiment, the clock signal CLK input from the clock input terminal 110 is supplied to a PLL (phase locked loop) circuit 120 thereby to generate a multiplied internal clock signal CK. The internal clock signal CK thus generated is carried by a wiring conductor LL provisionally almost to the center C0 of the main circuit block CB0 and supplied therefrom to each part in the block CB0 by H-shaped clock distribution conductors L10.

Though not shown, a duplicator for dividing an input signal into a plurality of signals and a buffer for shaping the waveform of a deformed signal are arranged at each diverging point of the clock distribution conductors (hereinafter referred to as the distribution conductors) L0. Also, each H-shaped clock distribution conductor L10 is formed to substantially the same length from the center C0 of the block to the terminal circuit (a flip-flop, a logic gate circuit, etc.) supplied with the clock. As a result, the clock skew in the block CB0 is considerably reduced as compared in the case where a clock distribution wiring conductor tree is formed over the whole chip. In this specification, the clock distribution line pattern may include clock distribution wiring conductors, a clock duplicator and a buffer.

Also, the blocks CB0 and CB1 to CB6 are each provided with interface circuits I/F1 to I/F6, I/F11, I/F 21, I/F 31, I/F 41, I/F 51 and I/F 61 for transmitting and receiving signals to and from the blocks. According to this embodiment, the interface circuits I/F 1 to I/F 6 of the main circuit block CB0 and the interface circuits I/F 11 to I/F 61 of the subsidiary blocks CB1 to CB6 are connected to each other by signal path groups 111 to 116.

The signal path groups 111 to 116 each include a clock signal path. The subsidiary blocks CB1 to CB6, on the other hand, include clock distribution conductors L10 to L60, respectively, branching in a H-shaped tree formed with substantially the same wiring conductor length from the centers C1 to C6, respectively, to the terminal circuit. The clock signal path in each of the signal path groups 111 to 116 is connected to the centers C1 to C6, respectively, of the respective blocks, from which a clock is supplied to the terminal circuit in each block.

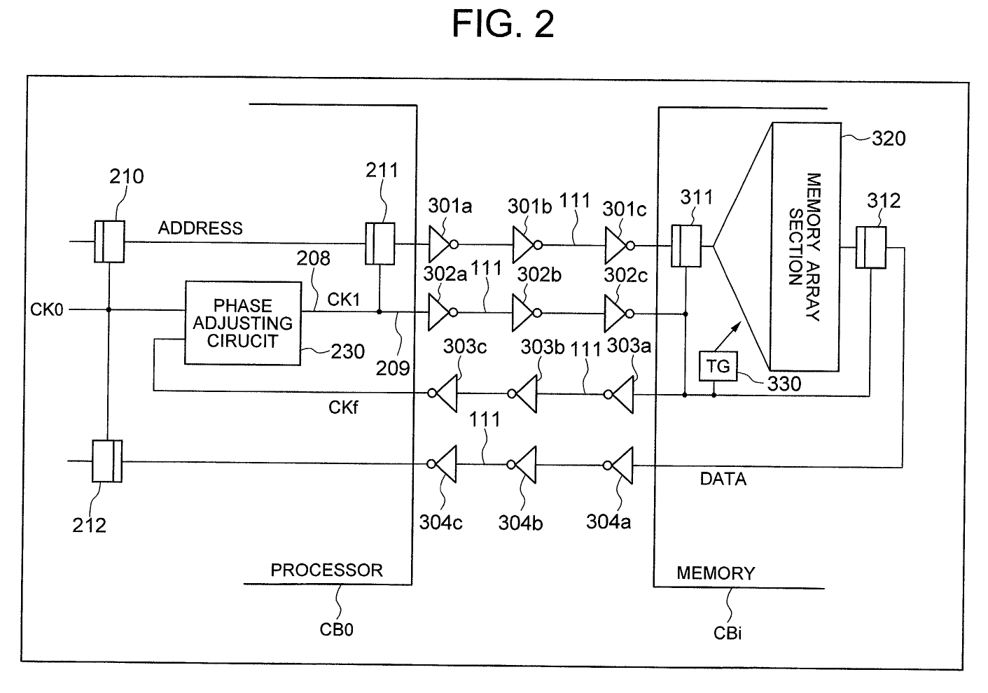

FIG. 2 shows in detail a section for transmitting/receiving the signals between the main circuit block CB0 and any one of the subsidiary circuit blocks CBi (i=1, 2, . . . ,6) in FIG. 1. Though not specifically limited, an example refers to a case in which the main circuit block CB0 is a processor and other subsidiary circuit blocks CBi are memories.

In the main circuit block CB0 of FIG. 2, numeral 210 designates an address latch circuit for latching an address generated for accessing a memory, numeral 211 an output latch circuit arranged in an interface circuit I/Fi, numeral 212 an input latch circuit for latching the data read from a memory as a subsidiary circuit block CBi, and numeral 230 a phase adjusting circuit for comparing the phase of the clock CK0 in the main circuit block CB0 with the phase of a feedback clock CKf from a subsidiary circuit block CBi and generating an output clock CK1 for attaining synchronization.

According to this embodiment, the output clock CK1 of the phase adjusting circuit 230 is supplied to the output latch circuit 211 on the side of the main circuit block CB0 and gives an output timing of the address data. Also, the address data latched in the output latch circuit 211 and the clock CK1 giving the output timing thereof are transmitted to the subsidiary circuit block CBi through the signal path group 111. FIG. 2 shows the address latch circuit 210 and only one signal path for transmitting the address data. Actually, however, a number of signal paths corresponding to the number of bits of the address are provided. The signal paths of the signal path group 111 are laid in parallel to each other and thus are formed to have the substantially same wiring conductor length, i.e. the substantially same delay. Buffer circuits 301a to 301c, 302a to 302c for shaping the waveform are arranged midway of each of the respective signal paths.

In the subsidiary circuit block CBi of FIG. 2, numeral 311 designates an address input latch circuit arranged in the interface circuit I/Fi, numeral 320 a memory array section including an address decoder and a sense amplifier, numeral 312 a data latch circuit (output latch circuit) for latching the data read from the memory array section 320, and numeral 330 a timing generator for generating an operation timing signal for the memory array section based on the clock CK1 supplied form the main circuit block CB0.

This embodiment is so configured that the input latch circuit 311 and the output latch circuit 312 of the subsidiary circuit block CBi perform the latch operation by the clock CK1 supplied to the subsidiary circuit block CBi in parallel to the transmission data through the signal group 111. The input latch circuit 311 of the subsidiary circuit block CBi latches the received data at the fall timing of the received clock CK1 in the case where the rise timing of the clock CK1 coincides with the switch timing of the transmission data, and at the rise timing of the received clock CK1 in the case where the fall timing of the clock CK1 coincides with the switch timing of the transmission data. Since the delay of the transmission data is substantially equal to the delay of the clock transmitted in parallel, the received data can be accurately latched regardless of the length of the delay time in the signal path group 111 by latching in the input latch circuit 311 the data received with the received clock CK1.

In the case where the subsidiary circuit block CBi is a memory as in this embodiment, a clock distribution line pattern in a complete form of H-shaped tree distribution conductors is difficult to implement. A clock distribution line pattern substantially similar to an isometric wiring conductor pattern can be employed, however, by designing all the wiring conductors to the same length from the timing generator to the circuit for receiving the timing signal generated by the generator or by designing the timing generator in such a manner that the output timing signal of the timing generator is generated at a timing taking the distance to the destination point into account beforehand.

In the case where the subsidiary circuit block CBi is a memory, on the other hand, the input address is latched in the input latch circuit 311 by the received clock CK1. At the same time, the data read from the memory array section 320 in accordance with the latched address and latched in the data latch circuit is transmitted to the main circuit block CB0 through the signal path group 111. The received clock CK1 is also transmitted as a feedback clock CKf to the main circuit block CB0 through the signal path group 111. Buffer circuits 303a, 303b, 303c, 304a, 304b, 304c for shaping the waveform are arranged midway of the signal path group 111.

As described above, the received clock CK1 is returned to the phase adjusting circuit 230 of the main circuit block CB0 as a feedback clock CKf, and the parallel clock CK1 is generated in such a manner that the clocks CK1 and CKf are in phase with each other. Thus, the data sent from the subsidiary circuit block CBi can be correctly taken or received the main circuit block CB0. Specifically, suppose the phase adjusting circuit 230 is absent. In such a case, when the main circuit block CB0 receives the data sent from the subsidiary circuit block CBi, the received data could not be correctly taken by the input latch circuit 212 in view of the fact that the switch timing of the received data is not coincident with the switch timing of the clock CK0 of the main circuit block CB0. According to this embodiment, in contrast, the provision of the phase adjusting circuit 230 and the generation of the parallel clock CK1 in phase with the clock CKf make it possible for the main circuit block CB0 to correctly take or receive the data sent from the subsidiary circuit block.

Also, the buffer circuits 301a to 301c, 302a to 302c, 303a to 303c, 304a to 304c for shaping the signal waveform are arranged midway of the signal path group 111. Even in the case where the main circuit block CB0 and the subsidiary circuit block CBi are distant from each other and the wiring conductors of the signal path group 111 are long with a large time constant, therefore, the transmission time required for the signal to arrive at the receiving end from the transmitting end can be reduced as compared with the the case in which the buffer circuits are absent. Further, in the case where the data of a plurality of bits are transmitted in parallel, the transmission variations between the bits can be suppressed. At the same time, the circuit block at the transmitting end can transmit a signal before the preceding signal previously transmitted reaches the circuit block at the receiving end. This system configuration can shorten the time required for transmitting continuous data.

Further, this embodiment is so configured that the clock signal path is connected to the centers C1 to C6 of the blocks wherefrom a clock is supplied to the terminal circuit in each block. Therefore, as long as the clock is not supplied, the operation of the subsidiary circuit block is stopped and thus the power consumption can be reduced for the LSI as a whole.

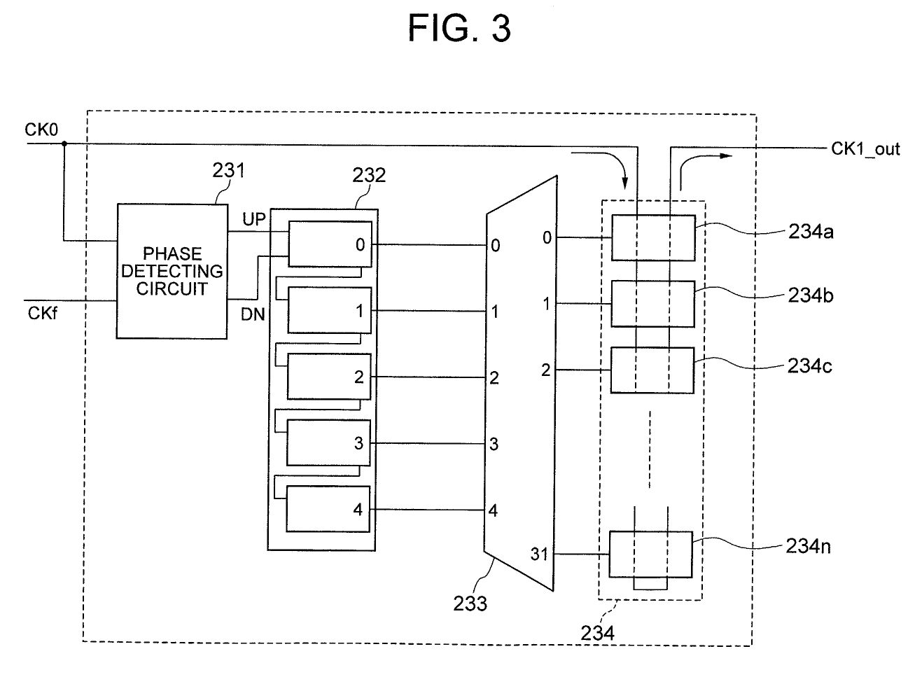

FIG. 3 shows a specific example of the phase adjusting circuit 230. The phase adjusting circuit 230 in this embodiment includes a phase detecting circuit 231 for comparing the internal clock CK0 of the main circuit block CB0 with the phase of the feedback clock CKf from the subsidiary circuit block CBi and outputting an up signal UP when the phase of the feedback clock CKf is delayed, and a down signal DN when the phase of the feedback clock CKf is ahead, a counter 232 for counting down in response to the output UP and counting up in response to the output DN from the phase detecting circuit 231, a decoder 233 for decoding the count of the counter 232 and generating a multi-bit decode signal with a bit corresponding to the count changing to high level, and a variable delay circuit 234 having cascaded delay stage circuits 234a to 234n corresponding to the output bits of the decoder 233.

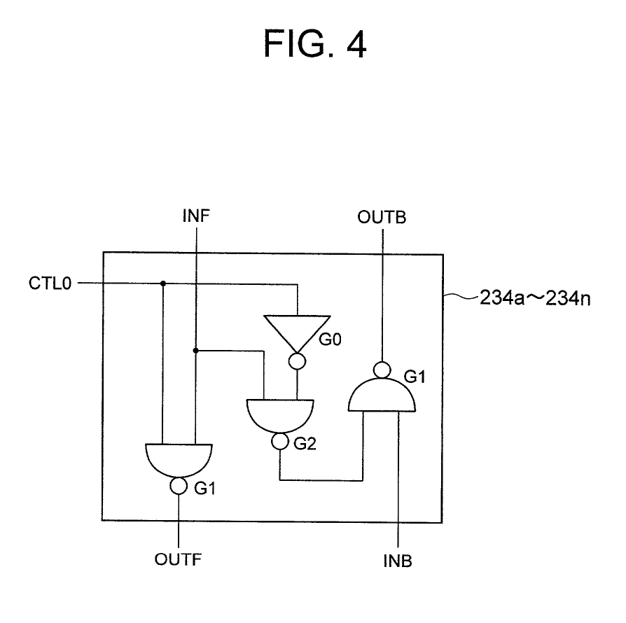

The delay stage circuits 234a to 234n are each configured of a combined circuit including three NAND gates G1 to G3 and an inverter G0 as shown in FIG. 4. When the control signal CTL0 is high in level, the input signal INF from the preceding stage circuit is transmitted to the next stage circuit as an output signal OUTF while at the same time transmitting the input signal INB from the next stage circuit to the preceding stage circuit as an output signal OUTB. When the control signal CTL0 is reduced to low level, on the other hand, the input signal INB from the next stage circuit is shut off and the input signal INF is directly returned to the preceding stage as an output signal OUTB.

A plurality of (say, 32) delay stage circuits having this configuration are connected in cascade as shown in FIG. 3, and the corresponding output bit of the decoder 233 is supplied as a control signal CTL0 to each of the delay stage circuits 234a to 234n. In this way, the clock CK0 input to the first delay stage circuit 234a is sequentially transmitted to the following delay stage circuits 234b, 234c and so forth, and turns back to the preceding delay stage circuits sequentially from a delay stage circuit corresponding to a “1” output bit of the decoder 233. This signal is output as a delay clock CK1 from the output terminal OUTB of the first delay stage circuit 234a. According to this embodiment, the delay time of the clock CK0 is changed with the number of the delay stage circuits for transmitting the clock CK0, which number in turn changes in accordance with the output of the decoder 233.

Specifically, assume that the delay time of each delay stage circuit is td. In the case where the clock is controlled to turn back in the ith delay stage circuit 234i of the variable delay circuit 234, for example, the clock CK1 is output delayed by 2i×td from the clock CK0. When the count of the counter 232 is reduced in response to the output UP of the counter 231, the delay time of the variable delay circuit 234 is shortened to advance the phase of the feedback clock CKf. In the case where the count of the counter 232 increases beyond the output DN of the counter 231, on the other hand, the delay time of the variable delay circuit 234 is lengthened thereby to delay the phase of the feedback clock CKf.

(Second Embodiment)

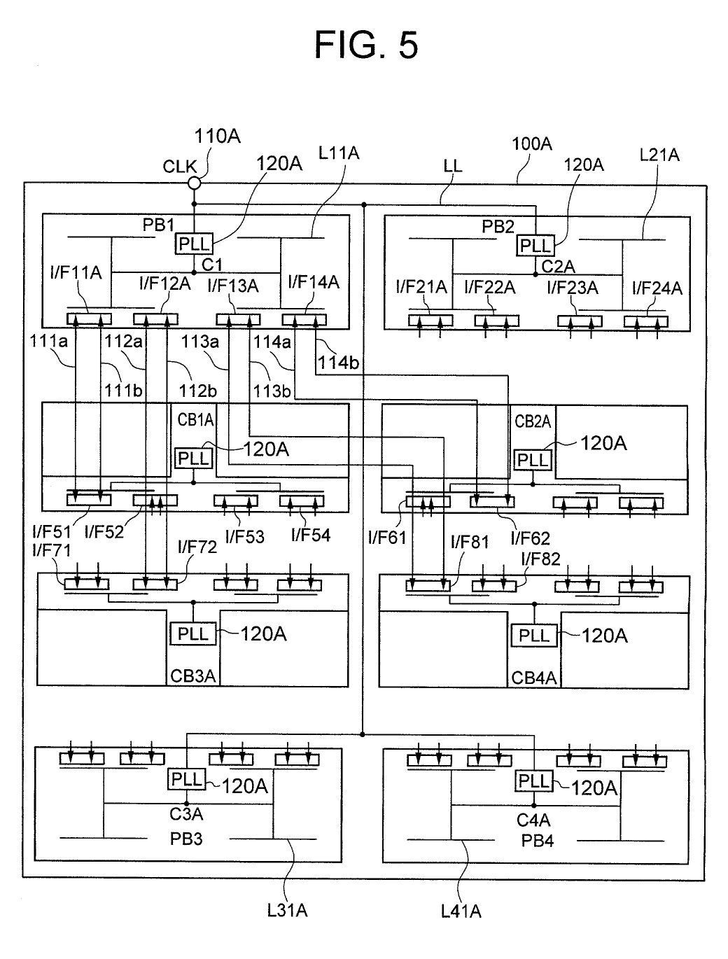

Now, a second embodiment of the invention will be explained with reference to FIGS. 5 to 9.

FIG. 5 shows a block configuration of a semiconductor integrated circuit as a whole and the connections for transmitting/receiving the signals between the blocks according to the second embodiment of the invention. In the second embodiment, as shown in FIG. 5, eight circuit blocks each having a substantially independent function are arranged on a single semiconductor chip 100A. The embodiment of FIG. 5 presupposes a multiprocessor system, in which among the eight blocks, four circuit blocks PB1, PB2, PB3, PB4 represent processors, and the remaining four circuit blocks CB1A, CB2A, CB3A, CB4A represent memories or peripheral modules.

According to this embodiment, a clock signal CLK of, say, 256 MHz input through a clock terminal 110A from an external source is used as a reference clock and multiplied to generate an internal clock CK0 of, say, 1 GHz in a PLL circuit 120A, which is provided in each circuit block. In the main circuit blocks PB1, PB2, PB3, PB4, the internal clock signal CK0 generated is provisionally transferred to the substantial centers C1A, C2A, C3A, C4A, respectively, of the circuit blocks, and from there, supplied to the various sections in each block by the H-shaped clock distribution conductors L11A, L21A, L31A, L41A. Though not shown, a duplicator for dividing an input signal into a plurality of signals and a buffer or the like for shaping the waveform of a deformed signal are arranged at each diverging point of the clock distribution conductor LL for supplying the clock signal CLK to the PLL circuit 120A in each of the main circuit blocks PB1, PB2, PB3 and PB4.

In the main circuit blocks PB1, PB2, PB3, PB4, the H-shaped clock distribution conductors L11A, L12A, L13A, L14A are formed to the same length from the center of each block to the terminal circuit (a flip-flop, a logic gate, etc.) supplied with a clock. As a result, the clock skew, even though present between the internal clocks of the blocks PB1 to PB4, is considerably reduced as compared with the case where the H-shaped clock distribution conductors are formed over the entire chip.

In the subsidiary circuit blocks CB1A, CB2A, CB3A, CB4A, the distribution conductors considered to have substantially the same length are formed by designing, in place of the perfectly H-shaped distribution conductors, wiring conductors of the same length from the PLL circuit 120 or the timing generator (not shown) for generating various internal timing signals based on the clock generated in the PLL circuit 120, to the circuit receiving the timing signal, or by designing, in place of the same H-shaped distribution conductors, a timing generator for generating each output timing signal at a timing taking the arrival time thereof into account.

The blocks PB1 to PB4 and CB1 to CB4 include interface circuits I/F 11A to I/F 14A and I/F 81 to I/F 84, respectively, for transmitting and receiving signals to and from the blocks. In this embodiment, the interface circuits I/F 11A to I/F 14A of the main circuit block PB1 are connected to the interface circuits I/F 51, I/F 62, I/F 72, I/F 81 of the subsidiary circuit blocks CB1 to CB4 by the signal path groups 111a, 111b, 114a, 114b, 112a, 112b, 113a, 113b. Of these signal path groups, the signal path groups 111b to 1114b each include a signal path for transmitting the clock in parallel.

Though not shown in FIG. 5, the interface circuits I/F 21A to I/F 24A of the main circuit block PB2 and the interface circuits I/F 52, I/F 61, I/F 71, I/F 82 of the subsidiary circuit blocks CB1 to CB4 are also connected to each other by similar signal path groups. These signal path groups also each include a signal path for transmitting the clock in parallel. This is also the case with the main circuit blocks PB3, PB4. According to this embodiment, the subsidiary circuit blocks CB1 to CB4 each include a PLL circuit 120 and are each configured to generate an internal clock based on a clock signal CLK supplied from an external source. A part or all of the subsidiary circuit blocks CB1 to CB4, like in the embodiment shown in FIG. 1, can be configured so that the clock transmitted in parallel from the main circuit blocks PB1 to PB4 is used as an internal clock.

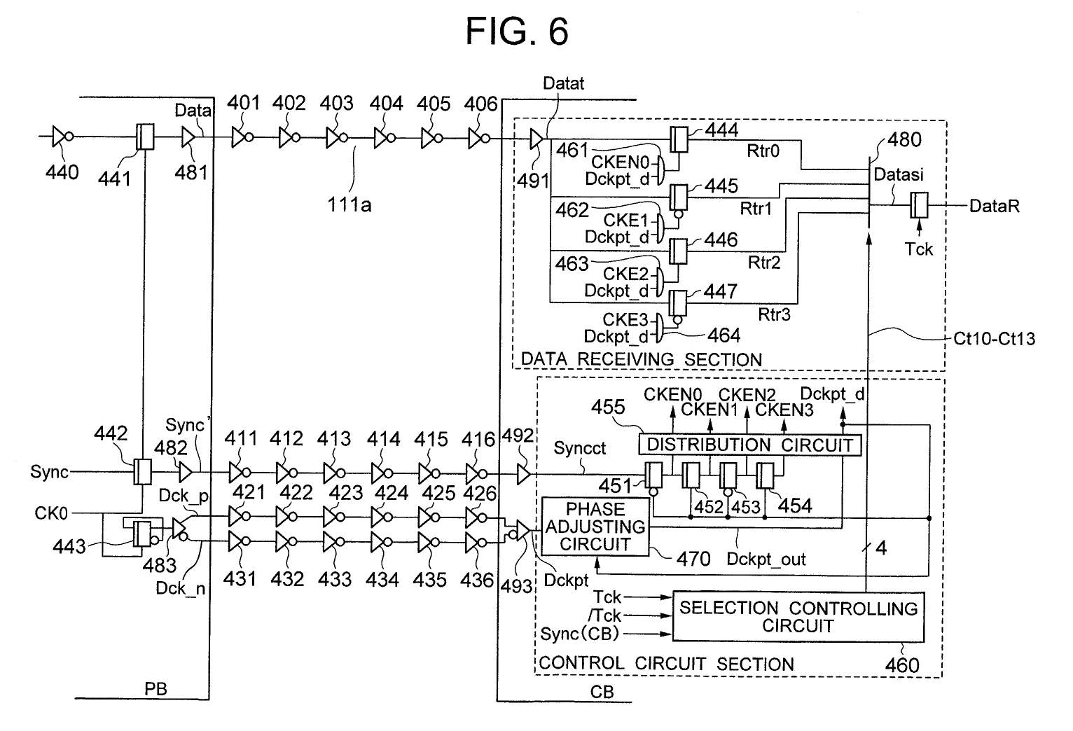

FIG. 6 shows in detail a section for transmitting/receiving the signal between a given one of the main circuit blocks PB1 to PB4 and a given one of the subsidiary circuit blocks CB1 to CB4 shown in FIG. 5.

In the main circuit block PB shown on the left side of FIG. 6, numeral 441 designates an output latch circuit for latching the data signal to be transmitted such as an address signal generated for accessing a memory and supplied from the internal circuit through the buffer 440, numeral 442 a latch circuit for latching the sync signal Sync (supplied from a CPU in the block PB) indicating the timing of transmitting the data from the main circuit blocks PB to the subsidiary circuit blocks CB, and numerals 481, 482 output buffer circuits for outputting the signal latched by the latch circuits 441, 442, respectively.

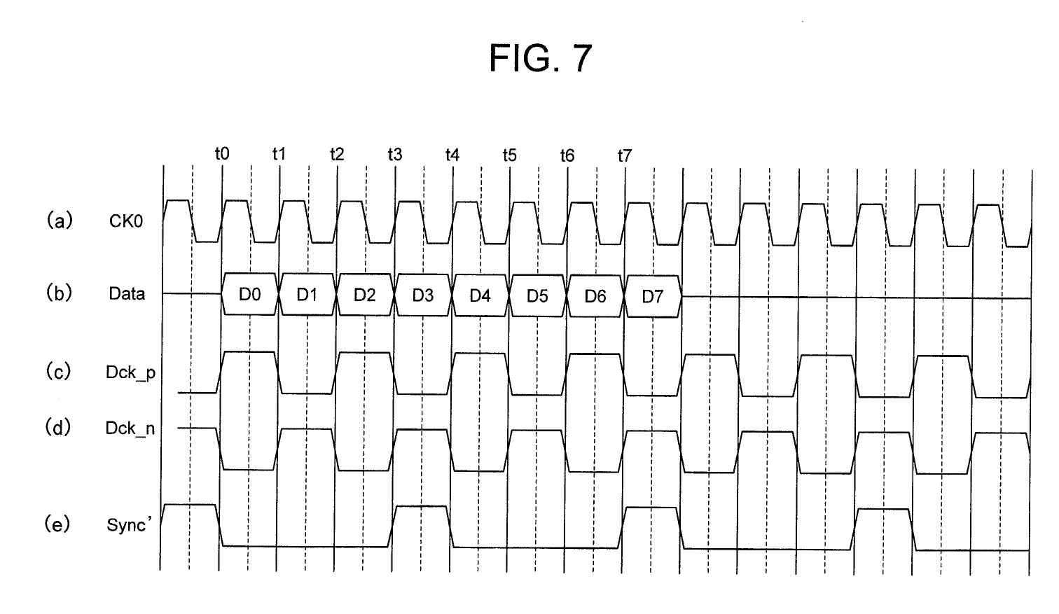

FIG. 6 shows the output latch circuit 441 and one signal path for transmitting an address. Actually, however, as many signal paths as the address bits are provided. The sync signal Sync, though not specifically limited, is such a signal which assumes a high level only for a period corresponding to the first bit of, for example, 4-bit data that may be transmitted (see (e) of FIG. 7).

Numeral 443 designates a frequency dividing circuit for dividing the frequency of the clock CK0 in the main circuit block PB into two frequencies, and numeral 483 an output buffer circuit for outputting differential signals Dck_p, Dck_n obtained by frequency division in the frequency dividing circuit 443. The output signals from the output buffer circuits 481 to 483 are supplied to the subsidiary circuit blocks CB through the signal path groups 111a, 111b. The signal paths of the signal path groups 111a, 111b are arranged in parallel to each other and thus have substantially the same length of wiring conductors, i.e. substantially the same delay. The buffers 401 to 406, 411 to 416, 421 to 426 and 431 to 436 for shaping the signal waveform are arranged midway of the signal paths, respectively, of the signal path groups 111a, 111b.

Though not specifically limited, the buffer circuits 401 to 406, 411 to 416, 421 to 426, 431 to 436 are arranged at intervals of, say, 1 to 3 mm on the semiconductor chip. As described above, this configuration has the advantage that the noise margin for clock transmission can be increased by transmitting the clock as a differential signal and also that the phase deviation of the timing of receiving the clock can be reduced at the receiving end. Also, the transmission of the clock divided into two frequencies leads to the advantage that the transfer frequency can be easily improved.

In the subsidiary circuit block CB shown on the right side of FIG. 6, numerals 491 to 493 designate input buffer circuits arranged at the other end (receiving end) of each signal path of the signal path groups 111a, 111b, numerals 444 to 447 input latch circuits for latching the data signal taken by the input buffer 491, numeral 480 a selector circuit for selecting one of the data latched by the input latch circuits 444 to 447, and numeral 448 a data latch circuit for latching the data selected by the selector circuit 480. Of these input buffers 491 to 493, the buffer 493 is a buffer circuit of differential input type.

Numeral 470 designates a phase regulating circuit for regulating the phase by delaying the clock Dckpt received by the buffer 493, and numerals 451 to 454 latch circuits for receiving and sequentially shifting the sync signal Synct received by the buffer 492, based on the clock Dckptd which is phase-regulated by the phase regulating circuit 470. Numeral 455 designates a distribution circuit for distributing the signal latched by the latch circuits 451 to 454 and the clock Dckpt_d phase-regulated by the phase regulating circuit 470, to the input latch circuits 444 to 447 as a clock Dckpt_d, together with the enable signal CKENO to CKEN3. Out of the signals output from the distribution line pattern wiring network 455, the clock Dckpt_d is fed back to the phase regulating circuit 470, which in turn compares the phase of the clock Dckpt_d fed back with the phase of the receiving clock Dckpt and regulates the two phases to be coincident with each other. Character Dckpt_d designates a clock generated by distribution of Dckpt_out in the distributing circuit 455.

Numeral 460 designates a selection control circuit for forming selection control signals Ct10 to Ct13 of the selector circuit 480. The selection control circuit 460 generates selection control signals Ct10 to Ct13 whereby the data latched by the input latch circuits 444 to 447 are sequentially selected by the selector circuit 480 and supplied to the data latch circuit 448 in a subsequent stage, based on the sync signal Sync(CB) distributed separately to the circuit block CB and the clocks Tck, /Tck of the subsidiary block CB. The signals Tck, /Tck, Sync(CB) input to the selection control circuit 460 give the timing of starting to form the selection control signals Ct10 to Ctl3 for correctly reading, in the order of reception, the data 444, 445, 446, 447, 444 and so forth latched in the input latch circuits 444 to 447. Thus, the data are prevented from being read, for example, in an erroneous order of 446, 447, 444, 445, 446 and so forth.

Now, the operation of transmitting and receiving the data and clock to the subsidiary circuit block CB from the main circuit block PB will be explained with reference to FIGS. 7 to 9.

According to this embodiment, the data Data synchronized with the clock CK0 of the main circuit block PB is output on the signal path group 111a by the output buffer circuit 481 of the main circuit block PB, as shown in (b) of FIG. 7. Also, differential clocks Dck-p, Dck-n having a double period and a half frequency of the clock CK0 of the main circuit block PB are output by the output buffer circuit 483 of the main circuit block PB, as shown in (c) and (d) of FIG. 7. Also, a sync signal Sync′ having a period four times longer than the clock CK0 is output on the signal path group 111b by the output buffer circuit 482, as shown in (e) of FIG. 7.

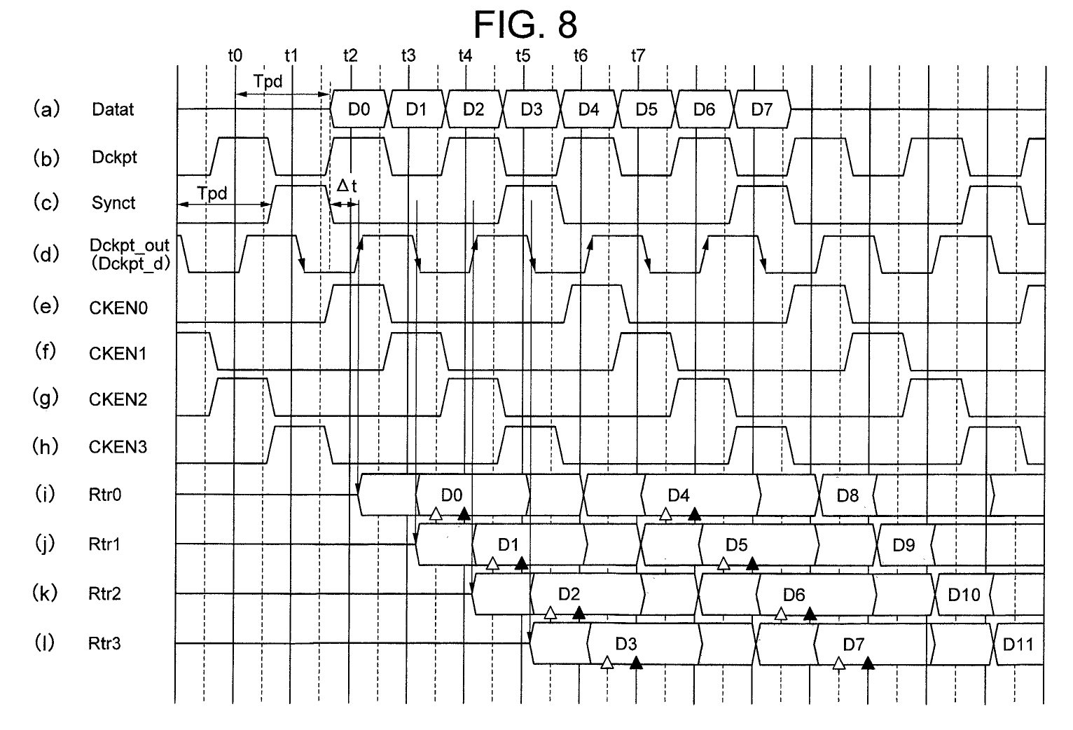

These signals Data, Sync′, Dck-p, Dck-n are, as shown in (a) to (c) of FIG. 8, are received as signals Datat, Synct, Dckpt, respectively, delayed by a predetermined delay time Tpd by the input buffer circuits 491, 492, 493 of the subsidiary circuit block CB. A delay clock Dckpt_out shown in (d) of FIG. 8 delayed by Δt from the receiving clock Dckpt is formed in the phase regulating circuit 470. This delay clock Dckpt_out causes the latch circuits 451 to 454 to perform the latch operation, so that four types of receiving enable signals CKEN0 to CKEN3 having a period four times longer than the delay clock Dckpt_out and 90° out of phase with each other are formed, as shown in (e) to (h) of FIG. 8. These signals are supplied to the input latch circuits 444 to 447 through the distributing circuit 455.

In the stage preceding to the latch trigger terminal of the input latch circuits 444 to 447, AND gates 461 to 464 are arranged each of which has one input terminal supplied with the receiving enable signals CKEN0 to CKEN3 and the other input terminal supplied with the delay clock Dckpt_d as a common input signal. The input latch circuits 444 to 447 corresponding to the AND gate with the receiving enable signals CKEN0 to CKEN3 at high level are caused to perform the latch operation by the leading edge or the trailing edge of the delay clock Dckpt_d, and sequentially take the data D0, D1, D2, D3, D4 and so forth on the signal paths, as shown in (i) to (l) of FIG. 8.

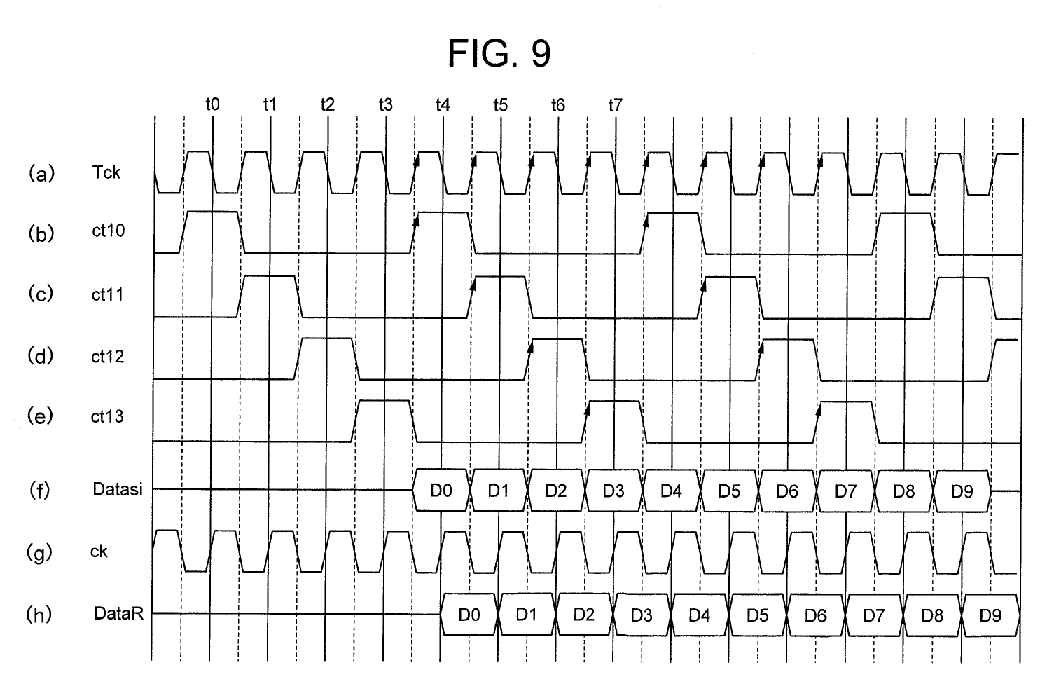

The data taken or received by the input latch circuits 444 to 447 are sequentially selected by the selector circuit 480 controlled by the selection control signals Ct10 to Ct13 having a timing as shown in (b) to (e) of FIG. 9 which are formed by the selection control circuit 460 based on the clock Tck of the subsidiary circuit block CB at the receiving end. The signals thus selected are supplied to the data latch circuit 448 in the next stage, which performs the latch operation in synchronism with the clock Tck of the subsidiary circuit block CB and sequentially takes the data Datasi (D0, D1, D2, D3, D4 and so forth) which are supplied to the internal circuit as the received data DataR.

As described above, according to this embodiment, the received data are sequentially taken by the input latch circuits 444 to 447 and subjected to serial-to-parallel conversion by the clock Dckpt_d generated by receiving the clock transmitted in parallel to the data. In this way, as shown in (i) to (l) of FIG. 8, the period during which each data is held is extended to four cycles. Within the period thus extended, the received data are sequentially selected and subjected to serial-to-parallel conversion based on the clock Tck of the subsidiary circuit block CB and supplied to the internal circuit. As a result, even in the case where the clock CK0 of the main circuit block CB at the transmitting end and the clock Tck of the subsidiary circuit block CB at the receiving end are considerably out of phase with each other, the received data can be taken correctly.

In the case where the clock CK0 at the transmitting end and the clock Tck at the receiving end have the same frequency, they are out of phase by a maximum of ±180°, even in which case the received data can be taken correctly by the method according to this embodiment as seen from FIG. 8. Also in the case where the frequency of the clock Tck at the receiving end is one half or three fourths of the frequency of the clock CK0 at the transmitting end, the data can be transmitted/received between the blocks by appropriately adjusting the number of the input latch circuits (444 to 447) or the timing of the selection control signals (Ct10 to Ct13) formed in the selection control circuit 460.

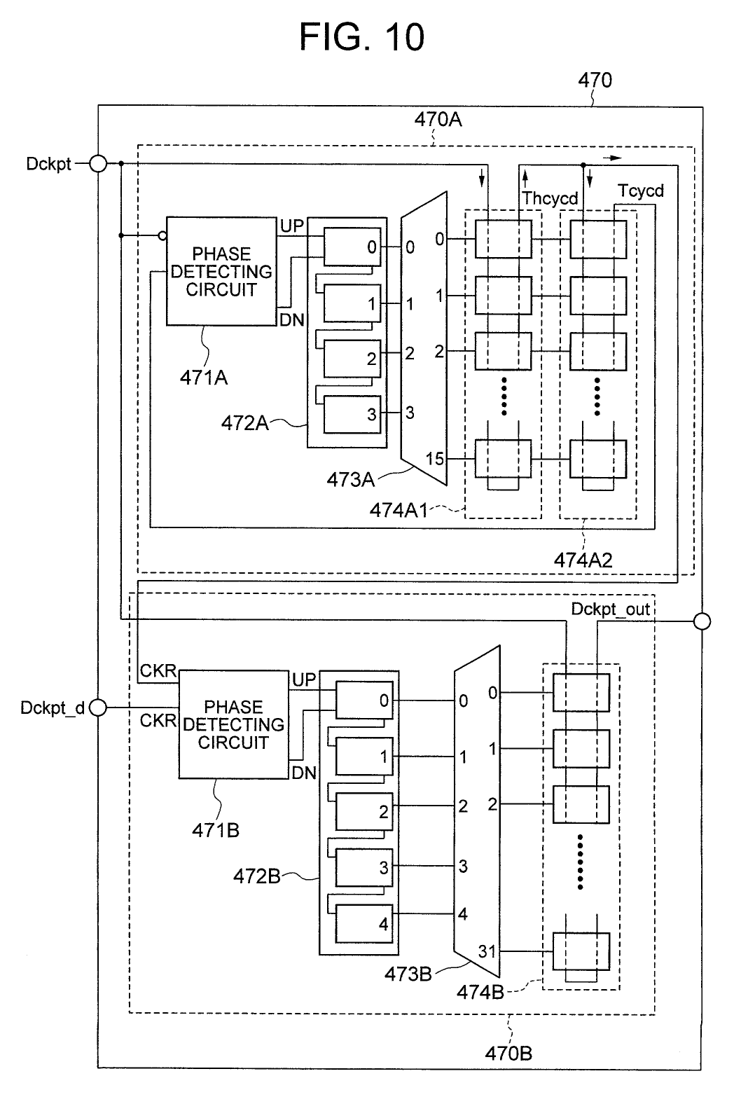

FIG. 10 shows a specific example of the circuit configuration of the phase regulating circuit 470. The phase regulating circuit 470 according to this embodiment includes a first DLL (Delay Locked Loop) circuit 470A having a similar configuration to the phase regulating circuit 230 shown in FIG. 3, and a second DLL circuit 470B connected to the subsequent stages. The second DLL circuit 470B in the subsequent stage has the same configuration as the circuit shown in FIG. 3. Specifically, the second DLL circuit 470B is configured of a phase detector 471B, a counter 472B, a decoder 473B and a variable delay circuit 474B having the same configuration as the phase detector 231, the counter 232, the decoder 233 and the variable delay circuit 234, respectively, shown in FIG. 3.

The first DLL circuit 470A in the preceding stage, on the other hand, is configured of variable delay circuits 474A1, 474A2 cascaded in two stages with a phase detector 471A, a counter 472A and a decoder 473A. The clock Dckpt delayed in the variable delay circuit 474A1 is output further delayed by the variable delay circuit 474A2. As evident from FIG. 10, the delay time of the variable delay circuit 474A1 and the variable delay circuit 474A2 assume the same value as a common output of the decoder 473A is supplied to both of them. The delay stage circuit making up the variable delay circuits 474A1, 474A2, 474B may be the same as the one shown in FIG. 4. The basic operation of each of the DLL circuits 470A, 470B is the same as that of the circuit shown in FIG. 3. Therefore, the difference will be mainly explained to avoid duplication.

The first DLL circuit 470A in the preceding stage uses the output clock Dckpt of the differential input buffer 493 receiving the clock from the main circuit block PB as a reference input clock, and the clock Tcycd delayed by the variable delay circuit 474A2 in the second stage as a feedback clock. The first DLL circuit 470A thus operates in such a manner that the phase difference between the trailing edge of the clock Dckpt and the leading edge of the clock Tcycd is detected by the phase detector 471A and is reduced to zero.

At the same time, the first DLL circuit 470A is so configured that the clock Thcycd delayed in the variable delay circuit 474A1 in the first stage is input to the variable delay circuit 474A2 in the second stage on the one hand and to the second DLL circuit 470B as a reference input clock at the same time. As a result, the first DLL circuit 470A functions as a half cycle phase shifting circuit which generates from the receiving clock Dckpt and supplies the second DLL circuit 470B with a clock one half period (one fourth of the period of the clock Dckpt) out of phase with the clock CK0 at the transmitting end.

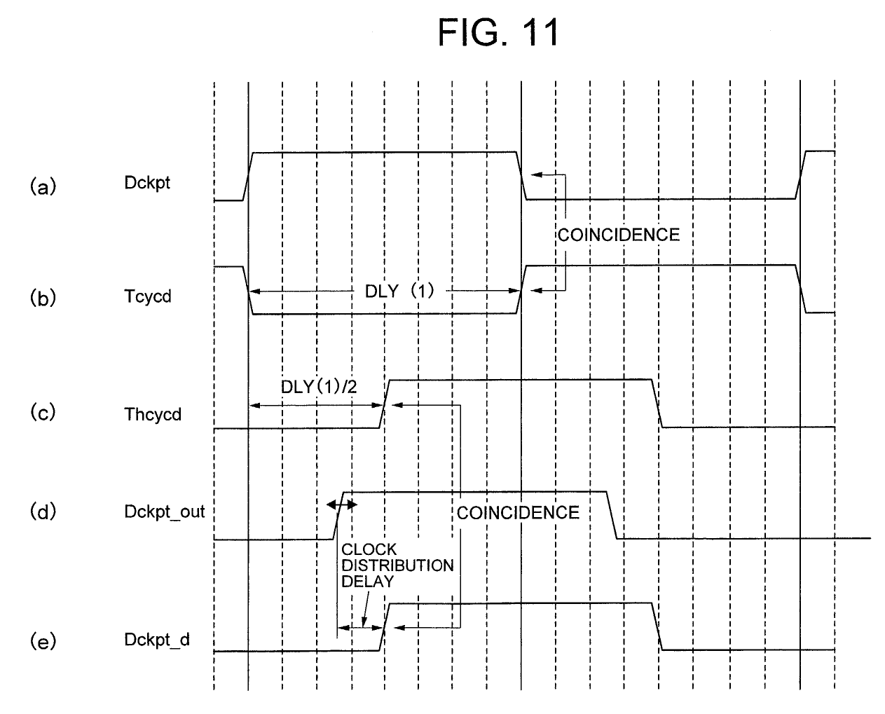

The second DLL circuit 470B, on the other hand, is supplied with the clock signal Dckpt_d as a feedback clock resulting from the distribution of the output clock Dckpt_out among the input latch circuits 444 to 447 by the distributing circuit 455 in FIG. 6, and operates in such a manner as to detect the phase difference between the feedback cock Dckpt_d (CKF) and the reference clock Thcycd (CKR) from the first DLL circuit 470A and reduce the phase difference to zero. As a result, the phase of the clock signal Dckpt_d distributed to the input latch circuits 444 to 447 is controlled to be located at the center between the changing points of the data transmitted from the main circuit block PB to the subsidiary circuit block CB. The timing control operation will be explained in more detail with reference to FIG. 11.

In the first DDL circuit 470A, as shown in (a) and (b) of FIG. 11, the phase difference between the trailing edge of the clock Dckpt and the leading edge of the delayed clock Tcycd is detected, and the clock Dckpt is delayed by an amount DLY thereby to generate the feedback side output clock Tcycd by the variable delay circuits 474A1, 474A2 in such a manner that the phase difference becomes 0. As a result, the feedback side output clock Tcycd becomes a clock delayed by one half of the period of the receiving clock Dckpt, i.e. by one period of the clock CK0 at the transmitting end. In the process, the delay amount of the variable delay circuit 474A1 and the delay amount of the variable delay circuit 474A2 are controlled to the same value. Therefore, the clock Thcycd output from the variable delay circuit 474A1, as shown in (c) of FIG. 11, becomes a clock delayed by one fourth of the period of the receiving clock Dckpt, i.e. by one half of the period of the clock CK0 at the transmitting end.

The clock Thcycd output from the variable delay circuit 474A1 is supplied to the second DLL circuit 470B and compared with the phase of the clock signal Dckpt_d distributed to the input latch circuits 444 to 447. Thus, the output clock Dckpt_out is generated with the phase difference of zero (see FIGS. 11(c) to (e)). As a result, even in the case where the number of bits of the data transmitted increases and the input latch circuits 444 to 44y are increased with an increased clock supply wiring conductor length so that the delay of the clock signal Dckpt_d distributed increases to an extent not negligible, the leading edge and the trailing edge of the clock signal Dckpt_d distributed to the input latch circuits 444 to 447 are controlled to be located at the center of the high-level period (one period of the clock CK0 of the block at the transmitting end) of the receiving clock Dckpt, i.e. at the center between the changing points of the data transmitted from the main circuit block PB to the subsidiary circuit block CB.

In the embodiment shown in FIG. 6, the deviation of the latch timing in each of the input latch circuits 444 to 447 can be reduced by designing the whole system in such a manner that the clock wiring conductors have the same length from the distributing circuit 455 to each of the input latch circuits 444 to 447 for receiving the clock signal Dckpt_d.

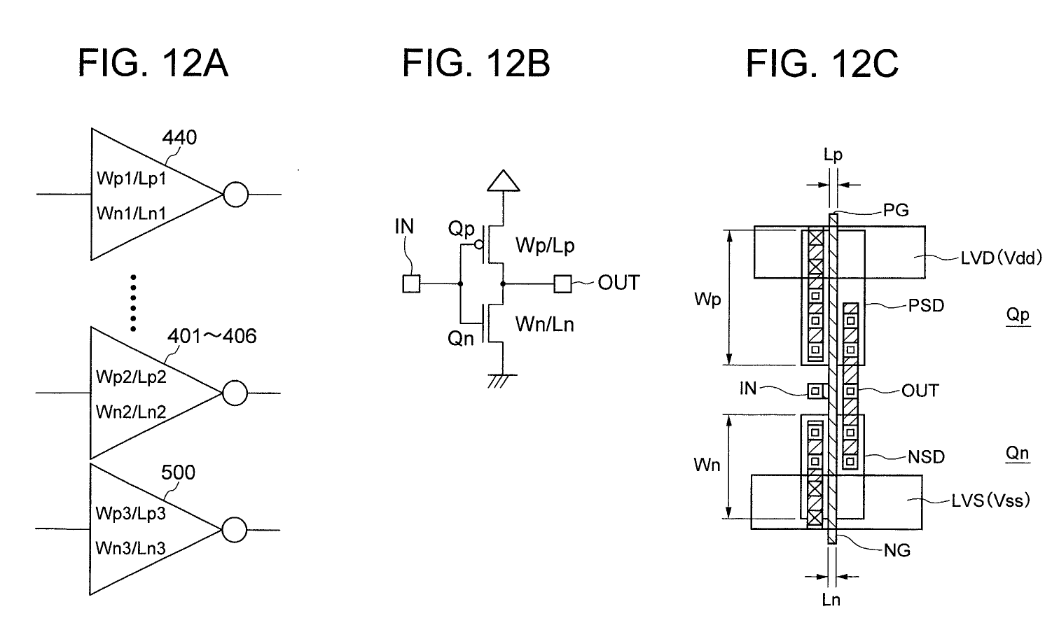

FIGS. 12A to 12C show a specific example of the buffer circuits arranged for transmitting the signal between the blocks of the semiconductor integrated circuit. In a semiconductor integrated circuit according to the present invention, as shown in FIG. 12A, a plurality of buffer circuits having different sizes, i.e. different driving forces are provided. The buffer circuit 440 in the main block PB shown in FIG. 6 and the waveform-shaping buffer circuits 401 to 406 arranged midway of the data transmission signal path making up the inter-block signal path group 111a and the output drive buffer circuit 500 are specific examples. The output drive buffer circuit 500 is for outputting a signal out of the semiconductor integrated circuit and not shown in the embodiments shown in FIGS. 1 and 5.

In FIG. 12A, the characters Wp1/Lp1, Wp2/Lp2 and Wp3/Lp3 attached to the buffers indicate the ratio between the gate width (Wp) and the gate length (Lp) of a p-channel MOSFET Qn in the case where each buffer includes the p-channel MOSFET Qp and an n-channel MOSFET Qn, as shown in FIG. 12B. Characters Wn1/Ln1, Wn2/Ln2 and Wn3/Ln3, on the other hand, are the ratio between the gate width (Wn) and the gate length (Ln) of the n-channel MOSFET Qn of each buffer. Character IN designates an input terminal of the buffer circuit and character OUT the output terminal of the buffer circuit.

The gate width Wp and the gate length Lp of the p-channel MOSFET and the gate width Wn and the gate length Ln of the n-channel MOSFET are such that, in FIG. 12C showing a layout of the p-channel MOSFET Qp and the n-channel MOSFET Qn, the width of the polysilicon gate electrode PG of the p-channel MOSFET Qp is given as Lp and the length of the crossing between the polysilicon gate electrode PG and the diffusion region PSD constituting the source-drain region of the p-channel MOSFET Qp is given as Wp. Also, in FIG. 12C, the width of the polysilicon gate electrode NG of the n-channel MOSFET Qn is assumed to be Ln, and the length of the crossing between the polysilicon gate electrode NG and the diffusion region NSD constituting the source-drain region of the n-channel MOSFET Qn is assumed to be Wn. Character LVD designates a power supply wiring conductor for supplying a source voltage VDD, and character LVS a power supply wiring conductor for supplying a source voltage VSS.

In this embodiment, the MOSFET making up each buffer is designed to hold the relations

Wp1/Lp1<Wp3/Lp3; Wn1/Ln1<Wn/Ln3,

Wp2/Lp2<Wp3/Lp3; Wn2/Ln2<Wn/Ln3.

Also, the waveform-shaping buffer circuits 421 to 426, 431 to 436 arranged midway of the inter-block clock transmission signal path are configured of a buffer circuit of a size nearest to the size of the waveform-shaping buffer circuits 401 to 406 arranged midway of the data transmission signal path. The waveform-shaping buffer circuits 411 to 416 arranged midway of the signal path for transmitting the sync signal Sync are also configured of a buffer circuit of a size nearest to the size of the buffer circuits 401 to 406.

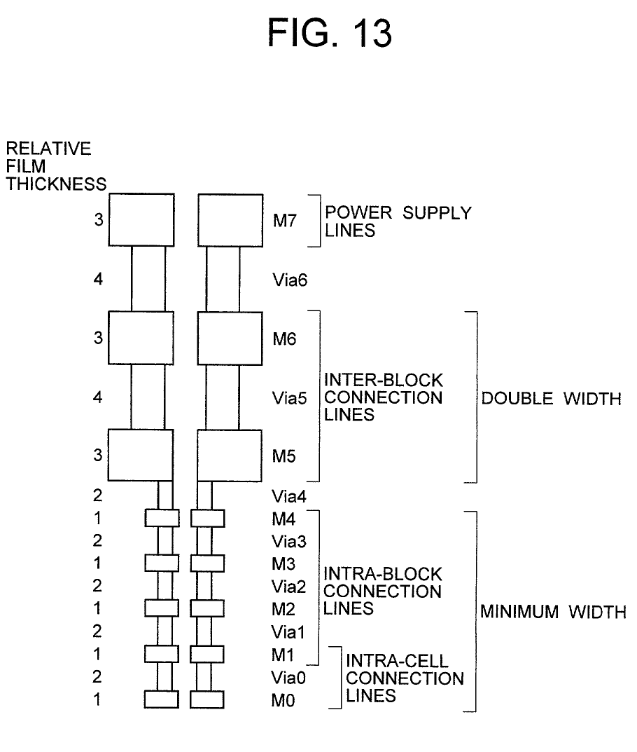

FIG. 13 shows a specific example of the wiring conductor structure of a semiconductor integrated circuit according to this invention.

Though not specifically limited, the semiconductor integrated circuit according to this embodiment comprises an eight-layer wiring conductor structure having eight metal layers. In FIG. 13, character M0 designates a first metal layer, character M1 a second metal layer, and so forth. Thus, character M7 designates an eighth metal layer. Each adjacent pair of the metal layers M0 to M7 are insulatively isolated by a layer insulating film not shown, and the conduction between each pair of adjacent upper and lower metal layers is secured by conductors Via0 to Via6 filled in the through holes formed in the insulating film. The metal layers M0 to M7 and the conductors Via0 to Via6 are formed of such metal as tungsten, copper, aluminum or titanium, and the layer insulating film is formed of, for example, silicon nitride, silicon oxide or PSG.

According to this embodiment, the metal layers M0 and M1 make up the internal connecting wiring conductors of the circuit for design units called the cells including a flip-flop, a latch circuit and a logic gate circuit. Similarly, the metal layers M1 to M4 make up the connecting wiring conductors in the circuit block, the metal layers M5, M6 make up the connecting wiring conductors between the circuit blocks, and the metal layer 7 makes up a power supply wiring conductor. The wiring conductors formed in the cells and the circuit blocks by the metal layers M0 to M4 have the smallest possible width machinable in the process. The wiring conductors between the blocks and the power supply wiring conductor formed of the metal layers M5 to M7, on the other hand, have a larger thickness than the wiring conductors of the metal layers M0 to M4 and have a width about twice the minimum width of the wiring conductors. Also, the intervals between wiring conductors for the metal layers M5 to M7 are rendered wider than the intervals between the wiring conductors for the metal layers M0 to M4.

As described above, according to this embodiment, the connection wiring conductors between the circuit blocks are formed of the metal layers M5, M6, and therefore, the transmission signal paths between the circuit blocks can be formed without increasing the chip size. Also, since the signal paths interfere with no wiring conductors in the blocks formed of the metal layers M0 to M4, the layout of the transmission signal paths between the circuit blocks can be easily designed.

The invention achieved by the inventor has been specifically described above with reference to embodiments. The present invention, however, is not limited to the embodiments described above but of course variously modifiable without departing from the scope thereof. In place of the phase regulating circuit including a phase detector, a counter and a decoder and a variable delay circuit having a combination of logic gates as a delay stage, for example, the invention is not limited to such a configuration but a configuration may be employed including a charge pump in place of the counter, a bias voltage generating circuit in place of the decoder and a variable delay circuit with a differential amplifier circuit as a delay stage operated by the current from a current source controlled by the bias voltage in place of the combination circuit.

The foregoing explanation refers to the case in which the invention achieved by the present inventor is used for a system LSI having a processor and memories built therein in the field of utilization providing the background of the invention. Nevertheless, the present invention is not limited to such a configuration, but widely applicable to the case in which a plurality of circuit blocks are mounted on a single semiconductor chip and it is desired to transmit data signals between the circuit blocks comparatively distant from each other.

According to the embodiments of the invention, the ratio of the clock skew to the transmission cycles, i.e. the clock period can be reduced, so that the operating frequency of the LSI can be improved while at the same time shortening the delay time for the long-distance data transmission in a chip and thus making possible accurate data transmission.

1. A semiconductor integrated circuit comprising:
a plurality of circuit blocks each having a clock distribution line pattern;
a first signal path for transmitting a data signal from said first circuit block to a second circuit block; and
at least a first buffer circuit connected to said first signal path in such a manner as to constitute said first signal path and at least a second buffer circuit connected to said second signal path in such a manner as to constitute said second signal path;
wherein said circuit blocks, said first and second signal paths, and said first and second buffer circuits are formed on a single semiconductor substrate;
wherein said clock signal and said data signal are transmitted in parallel to each other on said first and second signal paths, and said data signal is taken by said second circuit block by said clock signal; and
wherein said first and second signal paths have substantially the same wiring conductor length.

2. A semiconductor integrated circuit according to claim 1, wherein said first circuit block has an output latch circuit for latching the data signal to be transmitted, said second circuit block has an input latch circuit for latching the data signal to be received, and said output latch circuit and said input latch circuit are configured to perform the latch operation in response to the clock signals before and after, respectively, being transmitted from said first circuit block to said second circuit block.

3. A semiconductor integrated circuit according to claim 2, wherein said first circuit block is configured to send the next data signal and the clock signal to said first and second signal paths before arrival of the transmitted data signal clock signal at said second circuit block.

4. A semiconductor integrated circuit according to claim 1, wherein said second circuit block includes a plurality of circuits operated in synchronism with the internal clock generated based on the clock signal received from said second signal path, and said clock distribution line pattern of said second circuit block is configured to distribute said internal clock to said plurality of circuits through the substantially same length of path.

5. A semiconductor integrated circuit according to claim 4, wherein said circuit blocks are configured in such a manner that when said data signal is not sent out to said second circuit block from said first circuit block, said clock signal is not sent out from said first circuit block to said second circuit block.

6. A semiconductor integrated circuit according to claim 1, wherein a third signal path for feeding back the clock signal received by said second circuit block to said first circuit block is inserted between said first and second circuit blocks, and said first circuit block includes a phase adjusting circuit for adjusting the phase of the clock signal sent out from said first circuit block in such a manner that the clock signal in said first circuit block is in phase with the clock signal fed back.

7. A semiconductor integrated circuit according to claim 6, wherein said phase adjusting circuit includes a phase detecting circuit for generating a phase difference signal representing the phase difference obtained by comparing the phase of the clock signal in said first circuit block with the phase of said clock signal fed back, and variable delay circuits with the delay time thereof variable based on the phase difference signal from said phase detecting circuit.

8. A semiconductor integrated circuit according to claim 1, wherein said second circuit block includes a plurality of circuits operated in synchronism with a clock signal different from said clock signal received, and the clock distribution line pattern of said second circuit block is configured to distribute said different clock signal to said plurality of the circuits through paths having substantially the same length.

9. A semiconductor integrated circuit according to claim 8, wherein said second circuit block includes means for taking the serial data signal received from said first signal path, based on the received clock signal and storing said serial data signal for at least two periods of said received clock signal, and means for reading the data signal stored in said storage means by a clock signal different from said received clock signal.

10. A semiconductor integrated circuit according to claim 9,
wherein said second circuit block includes a phase shifting circuit for generating a clock signal out of phase by one half period of the data transmission cycle based on the received clock, and a phase adjusting circuit for generating a clock signal giving a timing of taking data to said holding means based on the clock signal generated by said phase shifting circuit, and
wherein said phase adjusting circuit operates to adjust the phase of the clock signal supplied to said holding means in such a manner that the clock signal generated by said phase-shifting circuit is in phase with the phase of the clock signal supplied to said holding means.

11. A semiconductor integrated circuit according to claim 10, wherein said holding means is configured to take said received data signal substantially at the center between the changing points of said received data signal.
